(19) United States
(12) Patent Application Publication
(10) Pub. No.: US 2024/0222331 A1
(43) Pub. Date: Jul. 4, 2024

(54) SEMICONDUCTOR PACKAGE AND METHOD FOR MANUFACTURING THE SAME

(71) Applicant: SAMSUNG ELECTRONICS CO., LTD., SUWON-SI (KR)

(72) Inventors: JIN-WOO PARK, Suwon-si (KR); UN-BYOUNG KANG, Suwon-si (KR); CHUNGSUN LEE, Suwon-si (KR)

(21) Appl. No.: 18/473,126

(22) Filed: Sep. 22, 2023

(30) Foreign Application Priority Data
Jan. 3, 2023 (KR) 10-2023-0000762

(51) Int. Cl. H01L 25/065; H01L 23/00

(52) U.S. Cl. CPC H01L 25/0657; H01L 24/03; H01L 24/05; H01L 24/09; H01L 24/16; H01L 24/32; H01L 24/73; H01L 24/81; H01L 2224/03462; H01L 2224/03464; H01L 2224/05573; H01L 2224/05644; H01L 2224/05687; H01L 2224/0569; H01L 2224/0903; H01L 2224/09152; H01L 2224/16014; H01L 2224/16148; H01L 2224/32145; H01L 2224/73204; H01L 2224/81203; H01L 2225/06513; H01L 2225/06541; H01L 2924/1431; H01L 2924/3511

(57) ABSTRACT

A semiconductor package includes a buffer chip configured to include a first dummy region and a second dummy region and to include first pads on rear surfaces of substrates of the first and second dummy regions; and a first core chip stacked at an upper portion of the buffer to include a bump 116 coupled to the first pad and positioned on an entire surface of the substrate, wherein the first pad is positioned in a line shape having a length including at least two bumps.

### CROSS-REFERENCE TO RELATED APPLICATION

This application claims priority under 35 U.S.C. § 119 to Korean Patent Application No. 10-2023-0000762, filed in the Korean Intellectual Property Office on Jan. 3, 2023, the entire contents of which are herein incorporated by reference.

### TECHNICAL FIELD

The present disclosure relates to a semiconductor package and a manufacturing method thereof.

### DESCRIPTION OF RELATED ART

Electronic devices are becoming more compact, lightweight, and multifunctional following rapid technological developments in the electronic industry and needs of users. Accordingly, there is a need for semiconductor packages used in the electronic devices to be miniaturized, lightweight, and multifunctional.

Research and development in semiconductor chip design has led to through silicon vias (TSV) and semiconductor packages having stacked structures, which may be used realize miniaturized, lightweight, and multifunctional semiconductor packages.

### SUMMARY

Embodiments provide a semiconductor package with improved reliability by appropriately controlling movement of an adhesive layer in a stack process.

An embodiment of the present disclosure provides a semiconductor package including: a first chip including a first dummy region, a second dummy region, and a plurality of first pads on a rear surfaces of the first chip in the first dummy region and the second dummy region; and a second chip stacked on the rear of the first chip and including a plurality of bumps coupled to the plurality of first pads, wherein each first pad of the plurality of first pads has a line shape having a length coupled to at least two bumps of the plurality of bumps.

The plurality of first pads may form at least one of a first line pattern, a second line pattern, or a third line pattern.

In this case, at least one of the first line pattern, the second line pattern, and the third line pattern may have a width of a bump of the plurality of bumps of the second chip.

The first line pattern may have a shape extending obliquely from a center of a side adjacent to an electrode region toward a corner of the first chip, wherein the electrode region separates the first dummy region and the second dummy region.

The second line pattern may have a line shape that is parallel to a direction of a first side of the first chip.

The third line pattern may have a line shape that is parallel to a direction of a second side of the first chip.

Specifically, at least one of the first line pattern, the second line pattern, or the third line pattern may include at least one of one line formed as a line, a plurality of lines in a form of dotted line, and a plurality of lines in a form of dashed-dotted line.

The at least one of the first line pattern, the second line pattern, and the third line pattern may have a width of at least two bumps of the plurality of bumps.

In an embodiment, the first chip may include an electrode region, the first dummy region may be positioned at a first side of the electrode region, and the second dummy region may be positioned at a second side of the electrode region, wherein the first side and the second side are opposite one another.

A first pattern of the plurality of first pads in the first dummy region mirrors the plurality of first pads in the second dummy region.

In a semiconductor package according to another embodiment, the plurality of first pads may further include a surface layer covering an upper surface of the plurality of first pads.

In this case, the surface layer may include at least one of a gold layer, an organic surface protection layer, and a silicon thin film layer, wherein the organic surface protection layer may include at least one of alkylbenzimidazole or diphenylimidazole, and wherein the silicon thin film layer may include SiN or SiO₂.

In an embodiment, the second chip may be stacked on the rear surface of the first chip using an adhesive layer provided therebetween, and the adhesive layer may include a non-conductive film (NCF) or an epoxy resin.

The plurality of first pads may include at least one of copper, a nickel/gold alloy, a copper/nickel/gold alloy, a copper/nickel/tin alloy, or cobalt.

In the first chip, a second pad on the rear surface of the first chip in an electrode region.

Herein, the first chip may include a through silicon via, and the second pad may be connected to the through silicon via.

Another embodiment of the present disclosure provides a semiconductor package including: a first chip including an electrode region, a first dummy region positioned at a first side of the electrode region, a second dummy region positioned at a second side of the electrode region, and a plurality of first pads positioned on a rear surface of the first chip in the first dummy region and second dummy region; and a second chip stacked on a rear surface of the first chip and including a plurality of bumps coupled to the plurality of first pads, wherein a first line pattern of the plurality of first pads has a shape extending obliquely from a center of a side adjacent to the electrode region toward a corner of the first chip, and the first dummy region and the second dummy region each include two of the first line patterns symmetrically positioned in a direction of a first side of the first chip.

An embodiment provides a manufacturing method of a semiconductor package, including: preparing a buffer chip including a through silicon via; forming a seed metal layer covering a rear surface of the buffer chip and the through silicon via; forming a mask pattern on the seed metal layer having a plurality of openings; forming a metal layer filling at least a portion of the plurality of openings of the mask pattern; and forming a plurality of first pads and a plurality of second pads on the rear surface of the buffer chip by removing the mask pattern and a seed metal layer positioned under the mask pattern, wherein each first pad of the plurality of first pads has a line shape having a length of at least two coupled to each first pad in a process of stacking a first core chip on an upper portion of the buffer chip.

In an embodiment, forming the plurality of first pads may include forming a first line pattern having a shape extending obliquely from a center of a side adjacent to an electrode region of the buffer chip toward a corner of the buffer chip, and wherein the plurality of second pads are formed in the electrode region.

In this case, the method may further include stacking the first core chip on the upper portion of the buffer chip, wherein at least two of the bumps are coupled to each first pad of the plurality of first pads

According to the embodiments, movement of the adhesive layer may be controlled in a bonding process including stacking semiconductor chips in multiple steps, by implementing the pads positioned in a dummy region in the form of a line having a length of at least two bump solders.

Specifically, during the bonding process, a solder shifting phenomenon may be reduced or prevented by controlling a flow direction of the adhesive layer toward the chip corner, by implementing various patterns of pads positioned in the dummy region. In addition, an extent of a metal portion may be increased on the rear surface of the substrate, and thus bonding between a lower chip and an upper chip may be firmly maintained, and accordingly, separation between the chips due to warpage or the like may be reduced or prevented.

As a result, according to an embodiment, reliability of the semiconductor package may be improved.

The various beneficial advantages and effects of the present disclosure are not limited to the above description, and will be more easily understood in the process of describing specific embodiments of the present disclosure.

### BRIEF DESCRIPTION OF THE DRAWINGS

FIG. 1 illustrates a top plan view showing a rear surface of a buffer chip in a semiconductor package according to an embodiment.

FIG. 2 illustrates a cross-sectional view taken along a line I-I′ of FIG. 1.

FIG. 3 illustrates an enlarged view for describing a region A in FIG. 2.

FIG. 4, FIG. 5, FIG. 6, and FIG. 7 respectively illustrate embodiments in which a pattern of a first pad positioned in first and second dummy regions are variously modified.

FIG. 8, FIG. 9, and FIG. 10 respectively illustrate embodiments in which a vertical cross-sectional structure of the first pad is variously modified.

FIG. 11, FIG. 12, FIG. 13, and FIG. 14 schematically illustrate a method of manufacturing a semiconductor package according to an embodiment.

### DETAILED DESCRIPTION

The present invention will be described more fully hereinafter with reference to the accompanying drawings, in which embodiments of the invention are shown. As those skilled in the art would realize, embodiments may be modified in different ways, all without departing from the spirit or scope of the present invention.

To clearly describe embodiments of the present invention, certain parts or portions that are irrelevant to the description may be omitted, and like numerals refer to like or similar constituent elements throughout the specification.

Further, since sizes and thicknesses of constituent members shown in the accompanying drawings may be arbitrarily given for better understanding and ease of description, the present invention is not limited to the illustrated sizes and thicknesses. In the drawings, the thicknesses of layers, films, panels, regions, etc., may be exaggerated for clarity. In the drawings, for better understanding and ease of description, the thicknesses of some layers and areas may be exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

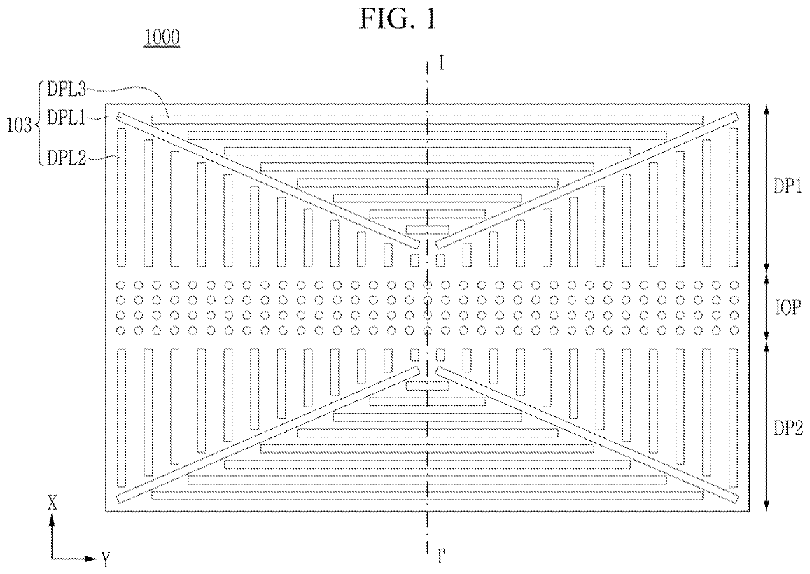

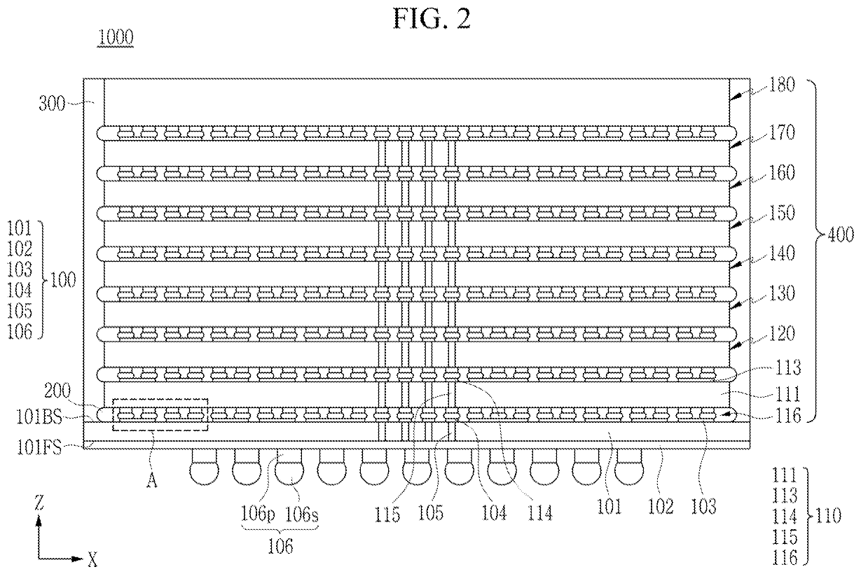

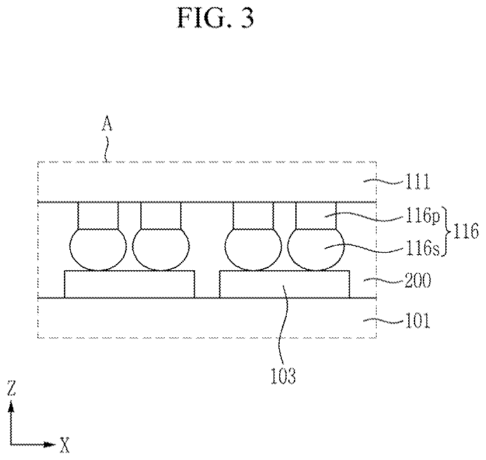

Hereinafter, a semiconductor package according to an embodiment will be described with reference to FIG. 1, FIG. 2, and FIG. 3.

FIG. 1 illustrates a top plan view showing a rear surface of a buffer chip in a semiconductor package 1000 according to an embodiment. In FIG. 1, only a substrate, a first pad, and a second pad are illustrated for convenience of description. FIG. 2 illustrates a cross-sectional view taken along a line I-I′ of FIG. 1. FIG. 3 illustrates an enlarged view for describing a region A in FIG. 2.

Referring to FIG. 2, the semiconductor package 1000 according to an embodiment may include a buffer chip 100, a chip stack portion 400, an adhesive layer 200, and a sealant 300.

The chip stack portion 400 may include a first core chip 110, a second core chip 120, a third core chip 130, a fourth core chip 140, a fifth core chip 150, a sixth core chip 160, a seventh core chip 170, and an eighth core chip 180. Specifically, the first to eighth core chips 110 to 180 may be sequentially stacked on the buffer chip 100 in a vertical direction (z direction).

Although eight core chips are illustrated in FIG. 2, embodiments are not limited thereto. That is, a number of core chips stacked on the buffer chip 100 may be variously changed.

An adhesive layer 200 may be provided between the buffer chip 100 and the first core chip 110. Similar adhesive layers may be provided between adjacent core chips among the first to eighth core chips 110 to 180. For example, an adhesive layer may be provided between the first core chip 110 and the second core chip 120.

As illustrated in FIG. 2, the adhesive layer 200 may protrude outward from side surfaces of the first to eighth core chips 110 to 180.

A more detailed description using the adhesive layer 200 provided between the buffer chip 100 and the first core chip 110 is described herein.

Referring to FIG. 2 and FIG. 3, the adhesive layer 200 may surround a side surface of a bump 116, a first pad 103, and a second pad 104. The adhesive layer 200 may surround other surfaces of the bump 116, the first pad 103, and the second pad 104, for example, an exposed upper surface of the first pad 103.

In an embodiment, the adhesive layer 200 may be formed of, e.g., a non-conductive film (NCF). For example, the NCF may be used as an adhesive layer when stacking the first core chip 110 on the buffer chip 100. The NCF may be used for bonding the respective core chips using a thermal compression bonding (TCB) method in a stacking process for stacking the second to eighth core chips 120 to 180, sequentially, on the first core chip 110.

In cases where the stack process is performed using the NCF, movement of the NCF may occur, and a phenomenon in which bump solder positioned between the buffer chip 100 and the first core chip 110, or between adjacent ones of the first to eighth core chips 110 to 180, may shift with the movement of the NCF.

In general, a bonding process of a TCB method may be performed such that bumps of an upper chip are bonded to rear surface pads of a lower chip by adhering the upper chip to the lower chip with a predetermined pressure at a high temperature, e.g., around 200 to 300° C. In the bonding process of the TCB method, the NCF and the bump solder may have fluidity through melting.

In particular, the integrated NCF may flow from a central portion of the upper chip or the lower chip to an outer portion in a concentric direction during the bonding process of the TCB method. Accordingly, in a rectangular-shaped chip including a chip corner and a chip side, the movement of the NCF may occur in which the NCF positioned at the chip side protrudes relatively more than the NCF positioned at the chip corner, and depending on the movement of the NCF, the bump solder may flow together with the NCF and a position of the bump solder may shift.

Accordingly, in the semiconductor package 1000 of an embodiment, as each first pad of a plurality of first pads, including the first pad 103, respectively positioned in a first dummy region DP1 and a second dummy region DP2 are arranged in a line shape having a length including at least two bumps 116, a movement direction of the NCF may be controlled toward the chip corner. The movement direction of the NCF may be controlled toward the chip corner by an electrode region in the first dummy region DP1 and the second dummy region DP2. The electrode region may be a metal portion.

Specifically, the buffer chip 100 may include an electrode region IOP, the first dummy region DP1, and the second dummy region DP2. For example, as illustrated in FIG. 1, the first dummy region DP1 may be positioned at a first side of the electrode region IOP in an x-axis direction, and the second dummy region DP2 may be positioned at a second side of the electrode region IOP in the x-axis direction. The electrode region IOP may be disposed between the first dummy region DP1 and the second dummy region DP2.

In this case, each of the first pads, including the first pad 103, positioned in the first dummy region DP1 and the second dummy region DP2 may be arranged in a line shape having a length including two or more bumps 116.

More specifically, the first pads positioned in the first dummy region DP1 may be arranged in at least one pattern among a first line pattern DPL1, a second line pattern DPL2, and a third line pattern DPL3.

Shapes of the first line pattern DPL1, the second line pattern DPL3, and the third line pattern DPL3 are described as viewed in a horizontal direction.

The first dummy region DP1 may have a rectangular shape. The first line pattern DPL1 may extend obliquely from a side adjacent to the electrode region IOP toward a corner of a substrate 101. The first line pattern DPL1 may be formed in a shape extending obliquely from a center of a side adjacent to the electrode region IOP toward a corner of a substrate 101.

In this case, as illustrated in FIG. 1, for example, the first line pattern DPL1 may be formed as a line. In addition, although not illustrated, a plurality of different line shapes may be formed. For example, a line shape may have a length including at least two bumps to form the first line pattern DPL1 in a dotted line shape. In another example, a line shape may have a first portion with a length including two bumps and a second portion with a length including three bumps, and first portions and second portions may be alternately arranged to form the first line pattern DPL1 in a dashed-dotted line shape. In addition, the first line pattern DPL1 may have a shape of at least one of a rectangle, a curve, a broken line, a quadrangle, or a polygon.

In addition, a width of the first line pattern DPL1 may be the same as that of the bump 116. Embodiments of the present disclosure are not limited thereto. That is, the width of the first line pattern DPL1 may be greater or less than the width of the bump 116.

The width of the bump 116 may be in a range of about 20 μm to 100 μm, for example. When a horizontal cross-section of the bump 116 is circular, the width of the bump 116 may be a diameter of the circle.

In the present specification, “same” indicates not only a completely same thing, but also a same thing including a difference that may occur due to a margin of error or the like in a process.

The first line patterns DPL1 may be symmetrically positioned from a center of the substrate 101 to corners of the substrate 101 of the buffer chip 100. Accordingly, two first line patterns DPL1 may be symmetrically positioned in the Y direction at each of the first dummy region DP1 and the second dummy region DP2.

The second line pattern DPL2 may be formed in a line shape that is parallel to a first side of the first dummy region DP1. The second line pattern DPL2 may be formed in a line shape that is parallel to a short side of the first dummy region DP1, for example, where the first dummy region DP1 has a rectangular shape.

For example, the second line pattern DPL2 may be positioned in an inner region adjacent to the electrode region IOP with respect to the first line pattern DPL1 in the first dummy region DP1. The second line pattern DPL2 may be formed in a shape that is parallel to the direction of the short side of the first dummy region DP1 and the x-axis. Lengths of the second line pattern DPL2 may decrease along an oblique line of the first line pattern DPL1 from an edge of the substrate 101 to the center of the substrate 101.

A width, a configuration, and a shape of the second line pattern DPL2 may be the same as those of the first line pattern DPL1.

The third line pattern DPL3 may be formed in a line shape that is parallel to a second side of the first dummy region DP1. The third line pattern DPL3 may be formed in a line shape that is parallel to a long side direction of the first dummy region DP1. That is, the third line pattern DPL3 may be perpendicular to the second line pattern DPL2.

For example, the third line pattern DPL3 may be positioned outside the first dummy region DP1 by a predetermined distance from the electrode region IOP based on the first line pattern DPL1. The third line pattern DPL3 may be formed in a shape that is parallel to the direction of the long side of the first dummy region DP1 and a y-axis direction. Lengths of the third line pattern DPL3 may decrease along an oblique line of the first line pattern DPL1 from an edge of the substrate 101 to a center of the substrate 101.

A width, a configuration, and a shape of the third line pattern DPL3 are the same as those of the first line pattern DPL1. As illustrated in FIG. 2 and FIG. 3, the width of the third line pattern DPL3 may be about equal to a width of two of the bumps 116 or about equal to a width of the first pads 103. For example, a line shape of the third line pattern DPL3 may have a width of two bumps 116.

In an embodiment, a first pattern formed by the plurality of first pads in the first dummy region DP1 may mirror a second pattern formed by the plurality of first pads in the second dummy region DP2 across the electrode region IOP. That is, the first dummy region DP1 and the second dummy region DP2 may be opposite one another across the electrode region IOP, and the plurality of first pads may have a same pattern on each side of the electrode region IOP.

In an embodiment, the first pads, including the first pad 103, and the second pads, including the second pad 104, are electrically insulated, and when the first pads are formed, an electrical short does not occur even when one or more of the first to third line patterns DPL1, DPL2, and DPL3 are connected to each other. Accordingly, a combined shape of the first to third line patterns DPL1, DPL2, and DPL3 may improve the movement of the NCF at the chip corner in a chip stacking process. The combined shape of the first to third line patterns DPL1, DPL2, and DPL3 is not particularly limited. The combined shape of the first to third line patterns DPL1, DPL2, and DPL3 may block the movement of NCF on the chip side. Various modifications of the first pads 103 including the first to third line patterns DPL1, DPL2, and DPL3 are contemplated.

In addition, a number of input or output terminals disposed in the first pads 103 positioned in the first dummy region DP1 and the second dummy region DP2 may be reduced or eliminated. As the first pads 103 may be positioned on a rear surface 101BS of the substrate 101 of the buffer chip 100, forming at least one of the first line patterns DPL1, the second line patterns DPL2, or the third line patterns DPL3, the bumps 116 may be positioned on a front surface of the substrate 111 of the first core chip 110, and the substrate 101 of the buffer chip 100 and the substrate 111 of the first core chip 110 may be stably fixed.

That is, in an embodiment, an extent of a metal portion on the rear surface of the substrate 101 may be increased by including the first pads 103, including various line patterns having a length including two or more bumps 116, on the rear surface of the substrate 101. Thus, when the first core chip 110 is stacked on the buffer chip 100 through a bonding process, or when the first to eighth core chips 110 to 180 are sequentially stacked, a bonding between substrates of a lower chip and an upper chip may be firmly maintained. Accordingly, it may be possible to reduce or prevent a separation problem between the buffer chip 100 and the first core chip 110 due to warpage or the like. Similarly, a separation problem between the first to eighth core chips 110 to 180 due to warpage or the like may also be reduced.

In addition, in the bonding process interposing the adhesive layer, a solder shifting phenomenon may occur, and may be large at chip corner portions of the buffer chip 100, between the buffer chip 100 and the first core chip 110 relative to other edge portions. Further, when bump solder 116s positioned in the chip corner portions is reflowed, the solder shifting phenomenon may result in a short-circuit defect or a contact defect. The short-circuit defect may be an electrical connection between input/output pins (not shown) at the chip corner portions, while the contact defect may include adjacent bump solders 116s stuck together, for example, due to the solder shifting phenomenon. However, in an embodiment, the first pads 103 may be positioned in a line shape having a length including two or more bumps 116 in the first dummy region DP1 and the second dummy region DP2, and in particular, the first pads 103 may be formed to include at least one of the first line pattern DPL1, the second line pattern DPL2, or the third line pattern DPL3 to improve the movement of the NCF at the chip corners. Thus in the bonding process, the movement of the adhesive layer 200 may be appropriately controlled. Accordingly, the above-described solder shifting phenomenon may be reduced or prevented from occurring, and reliability of the semiconductor package 1000 according to an embodiment may be improved.

While NCF is described as an example of the adhesive layer 200, according to an embodiment, even when a material formed by a molded underfill (MUF) method, e.g., an epoxy resin, is used as the adhesive layer 200, an effect of controlling the movement of the adhesive layer 200 may be the same.

Specifically, in the case of using a material formed by the molded underfill (MUF) method for the adhesive layer 200, a flow direction of the MUF method may be controlled by forming the first pads 103 in a line shape having a length including two or more bump solders 116s. is the first pads 103 having a line shape having a length including two or more bump solders 116s may be effective for void discharge and position control.

The first dummy region DP1 and the second dummy region DP2 may be formed in a same pattern, but are not limited thereto, and patterns of the first dummy region DP1 and the second dummy region DP2 may be formed differently.

The buffer chip 100 may include a second pad 104 positioned in the electrode region IOP of the rear surface 101BS of the substrate 101. A plurality of second pads, including the second pad 104, may be positioned, and each of the second pads may be positioned to be connected to a respective through silicon via (TSV). In particular, the second pad 104 may be position to be connected to TSV 105

The second pad 104 may have a circular flat plate shape. However, the shape of the second pad 104 is not limited to the circular flat plate shape, and for example, the second pad 104 may have an elliptical flat panel shape or a polygonal flat panel shape. In addition, the second pad 104 may have a three-dimensional structure. Although not illustrated, a protective insulating layer may be disposed on the rear surface 101BS of the substrate 101, and the TSV 105 may extend through the protective insulating layer. Accordingly, the second pad 104 may be positioned on the TSV 105 and the protective insulating layer.

A width of the second pad 104 may be about 15 μm to 50 μm.

In an embodiment, the first pad 103 and the second pad 104 may include, for example, at least one of copper (Cu), a nickel/gold alloy (Ni/Au), Cu/Ni/Au, a copper/nickel/tin alloy (Cu/Ni/Sn), or cobalt (Co).

The bumps 116 may be positioned above the first pad 103 and the second pad 104. The bumps 116 may be positioned on the first pad 103 and the second pad 104.

Referring to FIG. 3, the bumps 116 may include a bump pillar 116p and a bump solder 116s.

The bump pillar 116p may have a cylinder shape. The bump pillar 116p may include, for example, nickel (Ni), copper (Cu), palladium (Pd), platinum (Pt), gold (Au), or a combination thereof. According to an embodiment, a diffusion barrier layer and/or an adhesive layer may be formed between the bump pillar 116p and the bump solder 116s. The diffusion barrier layer may include, for example, nickel (Ni), cobalt (Co), copper (Cu), or a combination thereof. The adhesive layer may include, for example, nickel (Ni), copper (Cu), palladium (Pd), cobalt (Co), platinum (Pt), gold (Au), or a combination thereof.

The bump solder 116s may be positioned on the bump pillar 106p. The bump solder 116s may have a spherical or ball shape. The bump solder 116s may include, for example, tin (Sn), indium (In), bismuth (Bi), antimony (Sb), copper (Cu), silver (Ag), zinc (Zn), lead (Pb), and/or an alloy thereof. More specifically, the bump solder 116s may include Sn, Pb, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, and the like. An intermediate layer may be formed at a contact interface between the bump pillar 116p and the bump solder 116s. The intermediate layer may include an intermetallic compound (IMC), which may be formed by reacting metal materials included in the bump pillar 116p and the bump solder 116s at a relatively high temperature.

In an embodiment, the bump solder 116s positioned on the second pad 104 may correspond to an input/output pin. For example, the semiconductor package 1000 according to an embodiment may be a memory device. The memory device may include, for example, 1024 input/output pins. Accordingly, the 1024 second pads 104 corresponding to the bump solders 116s in a one-to-one manner may be positioned on the rear surface 101BS of the substrate 101 of the electrode region IOP of the buffer chip 100.

As such, the semiconductor package 1000 according to an embodiment may be implemented as a High-Bandwidth Memory (HBM) device supporting a wide input/output interface, and high-speed data processing.

The buffer chip 100 may be positioned at a lowermost portion of the semiconductor package 1000.

The buffer chip 100 may have a larger horizontal cross-section than a horizontal cross-section of the chip stack portion 400. However, the size of the buffer chip 100 is not limited thereto, and for example, the buffer chip 100 may have a same horizontal cross-section as the horizontal cross-section of the chip stack portion 400.

The buffer chip 100 may include a substrate 101, a device layer 102, a first pad 103, a second pad 104, a TSV 105, and a bump 106.

The substrate 101 may include, for example, a semiconductor element such as silicon (Si) or germanium (Ge). In addition, the substrate 101 may include a compound semiconductor such as silicon carbide (SiC), gallium arsenide (GaAs), indium arsenide (InAs), or indium phosphide (InP).

The substrate 101 may have a silicon on insulator (SOI) structure, and may include, for example, a buried oxide (BOX) layer. The substrate 101 may include a conductive region, e.g., a well doped with impurities or a structure doped with impurities. The substrate 101 may include various device isolation structures such as a shallow trench isolation (STI) structure.

The buffer chip 100 and the first to eighth core chips 110 to 180 may be electrically connected through TSVs. A structure of the TSVs will be described with reference to the TSV 105 positioned in the buffer chip 100 as follows.

In the buffer chip 100, the TSV 105 may penetrate the substrate 101 by extending from the rear surface 101BS to the front surface 101FS. In addition, although not illustrated, the TSV 105 may extend into the device layer 102. The TSV 105 may have a pillar shape. The TSV 105 may include a barrier film on an outer surface and a buried conductive layer in an interior thereof. The barrier layer may include at least one material of Ti, TiN, Ta, TaN, Ru, Co, Mn, WN, Ni, or NiB. The buried conductive layer may include at least one material of Cu alloys such as CuSn, CuMg, CuNi, CuZn, CuPd, CuAu, CuRe, and CuW, W and W alloys, Ni, Ru, or Co.

A via insulating layer may be provided between the TSV 105 and the substrate 101 or between the TSV 105 and the device layer 102. The via insulating layer may be formed of, for example, an oxide film, a nitride film, a carbide film, a polymer, or a combination thereof.

The device layer 102 may be positioned on the front surface 101FS of the substrate 101 of the buffer chip 100.

The device layer 102 may include various types of devices depending on a type of chip. For example, the device layer 102 may include various active and/or passive components, for example, a field effect transistor (FET) such as a planar FET or a FinFET, a memory such as a flash memory, a dynamic random access memory (DRAM), a static random access memory (SRAM), an electrically erasable programmable read-only memory (EEPROM), a phase-change random access memory (PRAM), a magnetoresistive random access memory (MRAM), a ferroelectric random access memory (FeRAM), or a resistive random access memory (RRAM), logic gate such as an AND, OR, or NOT, system large scale integration (LSI), a CMOS imaging sensor (CIS), or a micro-electro-mechanical system (MEMS).

In the semiconductor package 1000 according to an embodiment, the buffer chip 100 may include a plurality of logic devices in the device layer 102. Accordingly, the buffer chip 100 may be referred to as a logic chip. The buffer chip 100 may be positioned at a lower portion of the chip stack portion 400 in which the core chips 110 to 180 may be stacked to integrate and transmit signals of the core chips 110 to 180 to the outside of the semiconductor package 1000. The buffer chip 100 may be positioned at a lower portion of the chip stack portion 400 to transmit signals and power from the outside to the first to eighth core chips 110 to 180. Accordingly, the buffer chip 100 may also be referred to as a buffer chip or a control chip. In an embodiment, the first to eighth core chips 110 to 180 of the chip stack portion 400 may include a plurality of memory devices. Accordingly, the first to eighth core chips 110 to 180 may be referred to as memory chips.

The semiconductor package 1000 according to an embodiment may be, for example, a high bandwidth memory (HBM) module. The HBM module may be used for data processing for various purposes, and according to an embodiment, the HBM module may be used for a neural network calculation. As an example, the HBM module may perform neural network calculations according to various types of models such as convolutional neural networks (CNN), recurrent neural networks (RNN), multi-layer perceptron (MLP), deep belief networks, and restricted Boltzmann machines.

In the semiconductor package 1000 according to an embodiment, the buffer chip 100 is not limited to a logic chip or a buffer chip. For example, the buffer chip 100 may include a plurality of memory devices in the device layer 102. Accordingly, the buffer chip 100 may be a memory chip.

The device layer 102 may include at least two of the devices, a wiring structure electrically connecting the devices to a conductive region of the substrate 101, or an external connection terminal such as a bump 106. The wiring structure may include, for example, wires and/or contacts. The wiring structure may electrically connect the TSV 105 and the bump 106.

In the semiconductor package 1000 according to an embodiment, the device layer 102 may be disposed at a lower portion of the TSV 105. According to an embodiment, the device layer 102 may be disposed at an upper portion of the TSV 105. For example, a positional relationship between the device layer 102 and the TSV 105 may be relative.

Since detailed descriptions of the first pad 103 and the second pad 104 have been described above, a description thereof may be omitted in the following description.

The bump 106 may be disposed on a lower surface of the buffer chip 100. The bump 106 may be electrically connected to the TSV 105 through the wiring structure of the device layer 102. A detailed description of the bump 106 may be the same as that of the bump 116 of the first core chip 110, and a description thereof may be omitted in the following description.

The chip stack portion 400 may be stacked on the buffer chip 100. In the semiconductor package 1000 according to an embodiment, for the chip stack portion 400, a structure in which the first to eighth core chips 110 to 180 are stacked in a vertical direction is illustrated, but as described above, a number of core chips included in the chip stack portion 400 is not limited thereto.

Each of the first to eighth core chips 110 to 180 included in the chip stack portion 400 may have a structure similar to the structure of the buffer chip 100. For example, when described using the first core chip 110, the first core chip 110 may include a substrate 111, a first pad 113, a second pad 114, and a bump 116.

Herein, the substrate 111 may include a device layer (not illustrated) on an entire surface. In addition, the TSV 115 may be formed in a structure penetrating the substrate 111.

In addition, structures of the substrate 111, the first pad 113, the second pad 114, and the bump 116 are the same as those described above with reference to the first pad 103, the second pad 104, and the bump 106.

The sealant 300 may surround side surfaces of the chip stack portion 400 and the adhesive layer 200. Although FIG. 2 shows that an upper surface of the eighth core chip 180 is exposed, the sealant 300 may have a predetermined thickness to cover the upper surface of the eighth core chip 180 according to an embodiment.

The sealant 300 may be formed of, for example, an epoxy mold compound (EMC), but is not limited thereto.

In the semiconductor package 1000 according to an embodiment, an extent of a metal portion may be increased in the first dummy region DP1 and the second dummy region DP2 by implementing the first pads 103 positioned in the first dummy region DP1 and the second dummy region DP2 in a line shape having a length including at least two bump solders 116s. Accordingly, thermal conductivity of the first pad 103 may be improved. As a result, a wetting force of the bump solder 116s on the first pad 103 may reduce or prevent solder shifting. As such, by suppressing the solder shifting, it may be possible to improve contact between the first pad 103 and the bump 116 to firmly maintain a coupling between chips, and control warpage.

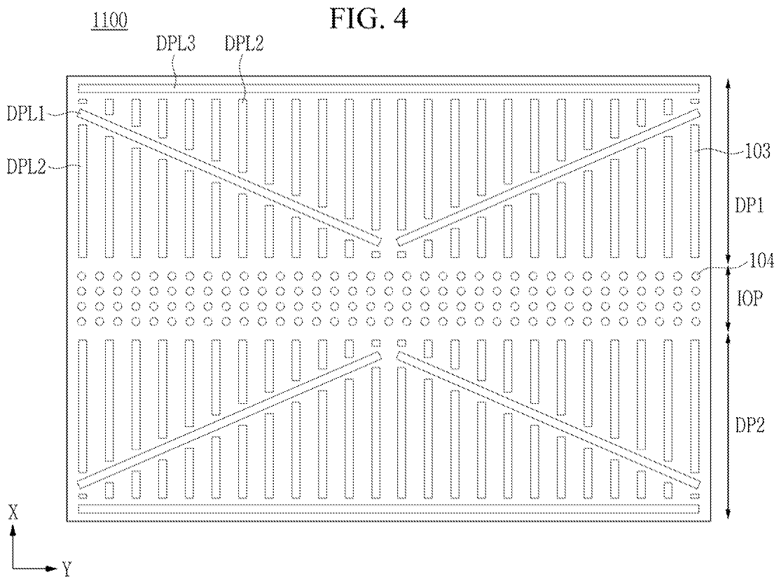

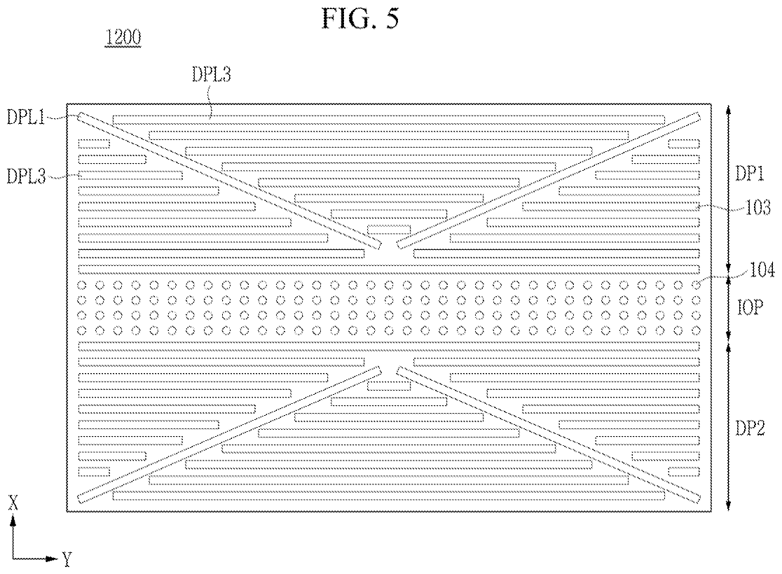

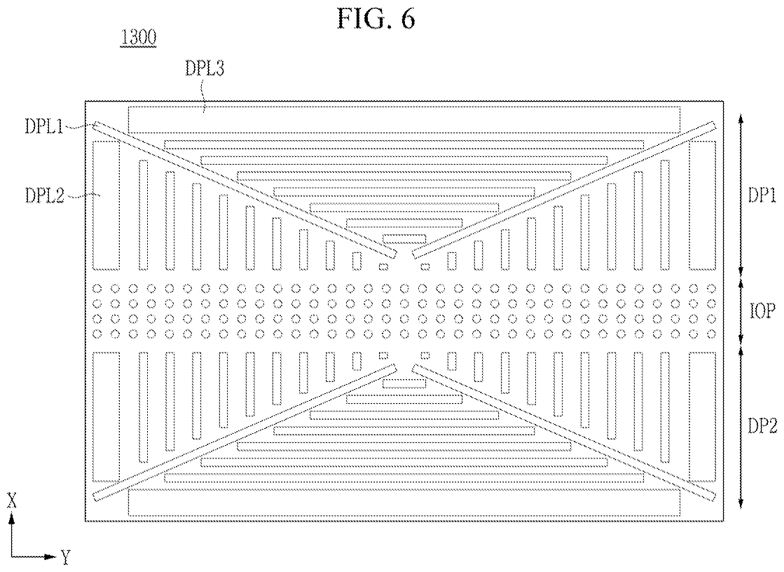

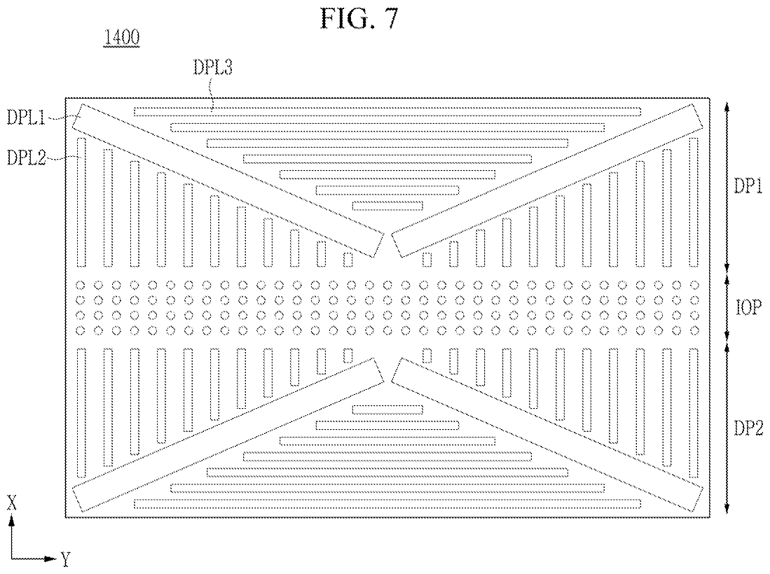

FIG. 4, FIG. 5, FIG. 6, and FIG. 7 respectively illustrate embodiments in which a pattern of a first pad positioned in first and second dummy regions are variously modified. In embodiments to be described below, repetitive descriptions may be omitted and differences between structures and functions may be described. In addition, the same reference numerals are used for the same components described elsewhere herein.

Referring to FIG. 4, in the semiconductor package 1100 according to an embodiment, the first pad 103 may include the first line pattern DPL1, the second line pattern DPL2, and the third line pattern DPL3.

For example, the second line pattern DPL2 may be positioned in an inner region of the first dummy region DP1 adjacent to the electrode region IOP and in an outer region of the first dummy region DP1 separated from the electrode region IOP by the first line pattern DPL1. The second line pattern DPL2 in the outer region may be positioned at a predetermined distance from the electrode region IOP with respect to the first line pattern DPL1. Lines of the second line pattern DPL2 may be formed in a shape in which a length increases along an oblique line of the first line pattern DPL1 from an edge to a center of the substrate. Accordingly, both the second line pattern DPL2 and the third line pattern DPL3 may be positioned in an outer region separated from the electrode region IOP by a predetermined distance based on the first line pattern DPL1 in the first dummy region DP1.

Referring to FIG. 5, in the semiconductor package 1200 according to an embodiment, the first pads, including first pad 103, may include the first line pattern DPL1 and the third line pattern DPL3.

For example, the third line pattern DPL3 may be positioned in the inner region of the first dummy region DP1 adjacent to the electrode region IOP and in the outer region of the first dummy region DP1 separated from the electrode region IOP by the first line pattern DPL1 in the first dummy region DP1. The third line pattern DPL3 may be positioned in the inner region may be formed in a shape in which a length decreases along an oblique line of the first line pattern DPL1 from an edge to a center of the substrate. Accordingly, in some embodiments, the second line pattern DPL2 having a line shape parallel to a direction of the short side of the first dummy region DP1 may be omitted.

Referring to FIG. 6, in the semiconductor package 1300 according to an embodiment, the first pads may include the first line pattern DPL1, the second line pattern DPL2, and the third line pattern DPL3.

In an embodiment, some lines of the second line pattern DPL2 and the third line pattern DPL3 may have a width including at least two bumps positioned on the first core chip.

For example, widths of lines of the second line pattern DPL2 and third line pattern DPL3 positioned at the edges of the substrate may include at least two bumps.

Referring to FIG. 7, in the semiconductor package 1400 according to an embodiment, the first pads may include the first line pattern DPL1, the second line pattern DPL2, and the third line pattern DPL3.

In an embodiment, a width of lines of the first line pattern DPL1 may include at least two bumps positioned on the first core chip.

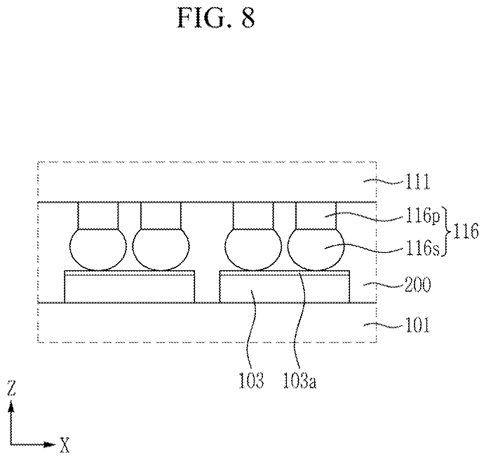

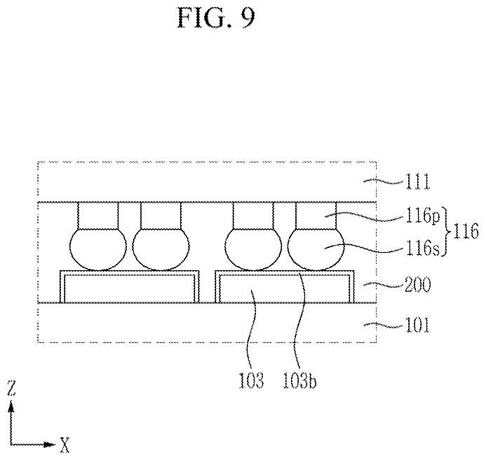

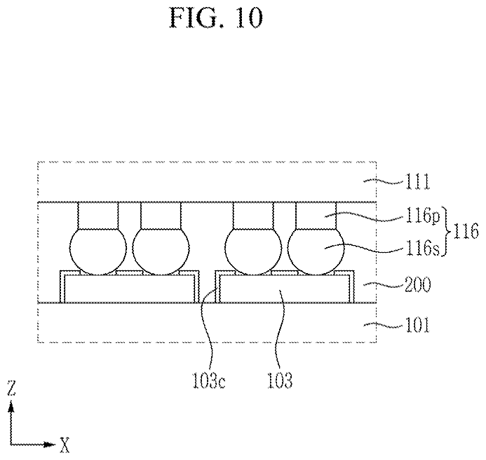

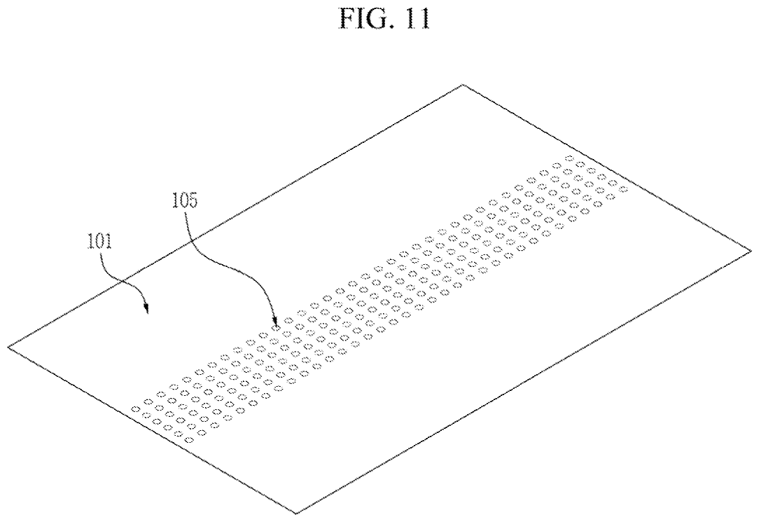

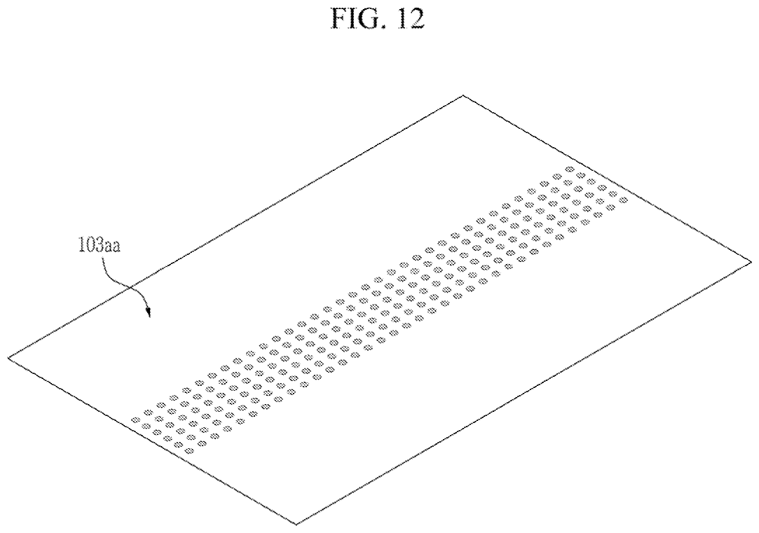

Various modifications of the pattern constituting the first pad illustrated in FIG. 7, FIG. 8, and FIG. 9 may control a flow direction of the adhesive layer toward a chip corner portion in a chip stack process interposing the adhesive layer therebetween. Accordingly, it may be possible to reduce or prevent warpage of a chip substrate by reducing or preventing a solder shifting phenomenon and firmly maintaining a coupling between adjacent chips.

FIG. 8, FIG. 9, and FIG. 10 respectively illustrate embodiments in which a vertical cross-sectional structure of the first pad is variously modified. In embodiments to be described below, repetitive descriptions may be omitted and differences between structures and functions may be described. In addition, the same reference numerals are used for the same components described elsewhere herein.

Referring to FIG. 8, FIG. 9, and FIG. 10, in some embodiments, the first pad 103 may include a surface layer covering an upper surface of the first pad 103. As such, when the surface layers 103a, 103b, or 103c are included on an upper surface of the first pad 103, a wetting characteristic of the bump solder 116s on the first pad 103 may be improved in a stacking process for sequentially stacking the buffer chip and the first core chip, or the first to eighth core chips. Accordingly, a solder shifting phenomenon may be suppressed.

Referring to FIG. 8, in an embodiment, in the first pad 103, the surface layer 103a may be an Au layer, which may be disposed on an upper surface of the first pad 103. The Au layer may be formed using a plating process, and for example, it may be formed by immersion plating, electroless plating, electroplating, or a combination thereof.

Referring to FIG. 9, according to an embodiment, in the first pad 103, an organic surface protection layer 103b may be disposed on the upper surface of the first pad 103.

The organic surface passivation layer may include at least one of alkylbenzimidazole or diphenylimidazole.

The organic surface protection layer 103b may be formed using, for example, at least one of dipping, spraying, or spin coating.

The first pad 103 may include copper (Cu), and thus when exposed to the air, the copper (Cu) may react with oxygen in the air to form a compound of oxygen and copper (Cu) on a surface thereof. When the bump solder 116s is attached to the first pad 103, the compound of oxygen and copper (Cu) may reduce an adhesive strength at an interface thereof.

Accordingly, in an disclosure, a surface of the first pad 103 may be protected from oxidation by disposing the organic surface protection layer 103b using a water-soluble antioxidant material on the surface of the first pad 103.

Referring to FIG. 10, in an embodiment, in the first pad 103, a silicon thin film layer 103c may be disposed on an upper surface of the first pad 103.

As illustrated in FIG. 10, the silicon thin film layer 103c may be formed with a structure excluding a portion where the bump solder 116s is attached, and thus the solder shifting phenomenon may be reduced or prevented.

The silicon thin film layer 103c may be formed using a chemical vapor deposition (CVD) process. The silicon thin film layer 103c may include at least one of silicon nitride (SiN) or silicon dioxide (SiO₂).

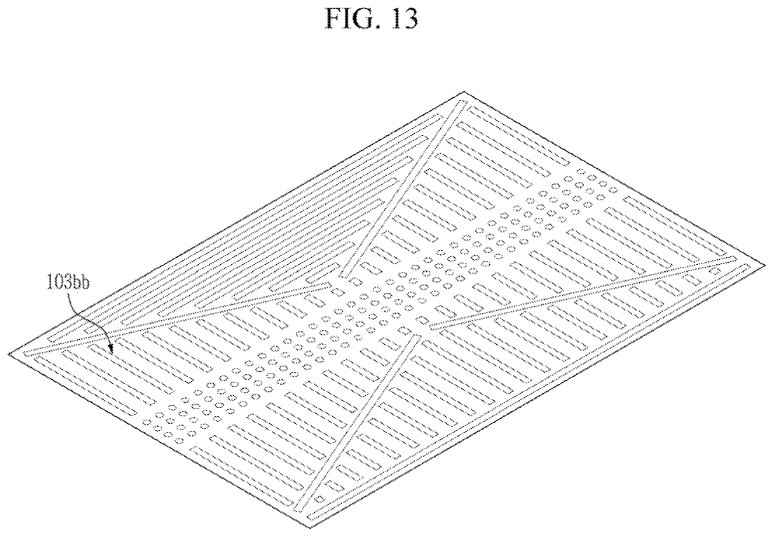

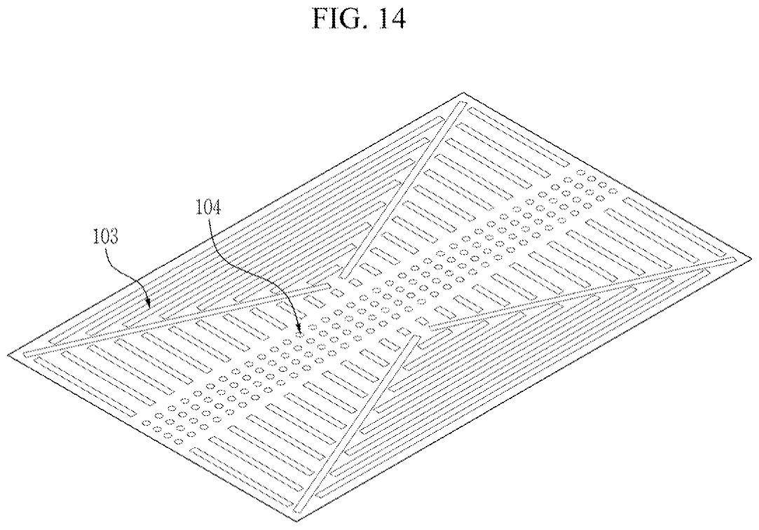

FIG. 11, FIG. 12, FIG. 13, and FIG. 14 schematically illustrate a method of manufacturing a semiconductor package according to an embodiment. Specifically, FIG. 11, FIG. 12, FIG. 13, and FIG. 14 schematically illustrate a method of forming a first pad and a second pad on a rear surface of a substrate.

Referring to FIG. 11, a buffer chip having a TSV 105 formed in a substrate 101 may be prepared.

In this case, a method of forming the TSV in the substrate of the buffer chip may be performed using a method known in the art, and is not particularly limited.

Referring to FIG. 12, a seed metal layer covering the rear surface of the substrate in which the TSV may be formed, and a mask pattern 103aa may be positioned on the seed metal layer.

The seed metal layer may be deposited by, for example, a sputtering method. A method of forming the seed metal layer is not limited thereto.

In addition, the seed metal layer may include, for example, Ti, Cu, Ni, Al, Pt, Au, Ag, W, Ta, Co, or any combination thereof.

The mask pattern 103aa may have a same opening as a shape and pattern of the first pad and the second pad. A portion of the seed metal layer may be exposed through the mask opening.

Specifically, the mask pattern 103aa may be formed, for example, through a patterning process using a photolithography technique for a photosensitive material film after forming the photosensitive material film on a seed metal layer. For a photolithography process, an exposure mask formed with a predetermined pattern may be used, and for example, a laser light source such as KrF or ArF may be used.

Referring to FIG. 13, a metal layer 103bb filling at least a portion of the mask opening may be formed. The metal layer 103bb may be formed to cover at least a portion of a surface of the seed metal layer exposed through the mask opening.

The metal layer 103bb may be formed through, for example, a plating method. The metal layer 103bb may be formed of a material constituting the first pad and the second pad. Example materials suitable for forming the first pad and the second pad have been described above, and will be omitted here.

The metal layer 103bb may be formed by a plating method using a seed metal layer as a seed. For example, the metal layer 103bb may be formed by immersion plating, electroless plating, electroplating, or a combination thereof.

Referring to FIG. 14, after forming the metal layer, a mask pattern and the seed metal layer under the mask pattern may be removed to form the first pad 103 and the second pad 104.

To remove the mask pattern, an ashing or strip process may be used, for example. In addition, after removing the mask pattern, a chemical etching method may be used to remove the seed metal layer under the mask pattern.

Herein, the first pad 103 may be formed in a line shape having a length including at least two bumps. A bump may be coupled to the first pad, and may be positioned on a front surface of the first core chip. The first core chip may be stacked at an upper portion of the buffer chip, and bumps coupled to the first pad may be disposed on an entire surface of the substrate, as described herein.

While this disclosure has been described in connection with what is presently considered to be practical embodiments, it is to be understood that the invention is not limited to disclosed embodiments, and the disclosure is intended to cover various modifications and equivalent arrangements included within the spirit and scope of the appended claims.

What is claimed is:

1. A semiconductor package comprising:
a first chip including a first dummy region, a second dummy region, and a plurality of first pads on a rear surface of the first chip in the first dummy region and the second dummy region; and
a second chip stacked on the rear surface of the first chip and including a plurality of bumps coupled to the plurality of first pads,
wherein each first pad of the plurality of first pads has a line shape having a length coupled to at least two bumps of the plurality of bumps.

2. The semiconductor package of claim 1, wherein the plurality of first pads form at least one of a first line pattern, a second line pattern, or a third line pattern.

3. The semiconductor package of claim 2, wherein at least one of the first line pattern, the second line pattern, and the third line pattern has a width of a bump of the plurality of bumps of the second chip.

4. The semiconductor package of claim 2, wherein the first line pattern has a shape extending obliquely from a center of a side adjacent to an electrode region toward a corner of the first chip, wherein the electrode region separates the first dummy region and the second dummy region.

5. The semiconductor package of claim 2, wherein the second line pattern has a line shape that is parallel to a direction of a first side of the first chip.

6. The semiconductor package of claim 2, wherein the third line pattern has a line shape that is parallel to a direction of a second side of the first chip.

7. The semiconductor package of claim 2, wherein at least one of the first line pattern, the second line pattern, or the third line pattern includes at least one of one line formed as a line, a plurality of lines in a form of a dotted line, and a plurality of lines in a form of dashed-dotted line.

8. The semiconductor package of claim 2, wherein at least one of the first line pattern, the second line pattern, and the third line pattern has a width of at least two bumps of the plurality of bumps.

9. The semiconductor package of claim 1, wherein the first chip includes an electrode region, the first dummy region is positioned at a first side of the electrode region, and the second dummy region is positioned at a second side of the electrode region, wherein the first side and the second side are opposite one another.

10. The semiconductor package of claim 1, wherein a first pattern of the plurality of first pads in the first dummy region mirrors a second pattern of the plurality of first pads in the second dummy region.

11. The semiconductor package of claim 1, wherein the plurality of first pads comprise a surface layer covering an upper surface of the plurality of first pads.

12. The semiconductor package of claim 11, wherein the surface layer includes at least one of a gold layer, an organic surface protection layer, or a silicon thin film layer,
wherein the organic surface protection layer includes at least one of alkylbenzimidazole or diphenylimidazole, and
wherein the silicon thin film layer includes at least one of silicon nitride or silicon dioxide.

13. The semiconductor package of claim 1, wherein the second chip is stacked on the rear surface of the first chip using an adhesive layer provided therebetween, and the adhesive layer includes a non-conductive film (NCF) or an epoxy resin.

14. The semiconductor package of claim 1, wherein the plurality of first pads include at least one of copper, a nickel/gold alloy, a copper/nickel/gold alloy, a copper/nickel/tin alloy, or cobalt.

15. The semiconductor package of claim 2, further comprising a second pad on the rear surface of the first chip in an electrode region.

16. The semiconductor package of claim 15, wherein the first chip includes a through silicon via, and the second pad is connected to the through silicon via.

17. A semiconductor package comprising:
a first chip including an electrode region, a first dummy region positioned at a first side of the electrode region, a second dummy region positioned at a second side of the electrode region, and a plurality of first pads positioned on a rear surface of the first chip in the first dummy region and the second dummy region; and
a second chip stacked on the rear surface of the first chip and including a plurality of bumps coupled to the plurality of first pads,
wherein a first line pattern of the plurality of first pads has a shape extending obliquely from a center of a side adjacent to the electrode region toward a corner of the first chip, and
the first dummy region and the second dummy region each include two of the first line patterns symmetrically positioned in a direction of a first side of the first chip.

18. A method of manufacturing a semiconductor package, comprising:
preparing a buffer chip including a through silicon via;
forming a seed metal layer covering a rear surface of the buffer chip and the through silicon via;
forming a mask pattern on the seed metal layer having a plurality of openings;
forming a metal layer filling at least a portion of the plurality of openings of the mask pattern; and
forming a plurality of first pads and a plurality of second pads on the rear surface of the buffer chip by removing the mask pattern and a seed metal layer positioned under the mask pattern,
wherein each first pad of the plurality of first pads has a line shape having a length of at least two bumps coupled to each first pad in a process of stacking a first core chip on an upper portion of the buffer chip.

19. The method of claim 18, wherein forming the plurality of first pads comprises forming a first line pattern having a shape extending obliquely from a center of a side adjacent to an electrode region of the buffer chip toward a corner of the buffer chip, and wherein the plurality of second pads are formed in the electrode region.

20. The method of claim 18, further comprising stacking the first core chip on the upper portion of the buffer chip, wherein at least two of the bumps are coupled to each first pad of the plurality of first pads.
